(19) United States
(12) Patent Application Publication
(10) Pub. No.: US 2011/0316005 A1
(43) Pub. Date: Dec. 29, 2011

(54) DISPLAY APPARATUS

(75) Inventors: Takehiro Murao, Osaka (JP); Naru Usukura, Osaka (JP); Akizumi Fujioka, Osaka (JP); Akinori Kubota, Osaka (JP); Seishi Kosegawa, Osaka (JP); Toshiyuki Yoshimizu, Osaka (JP)

(73) Assignee: SHARP KABUSHIKI KAISHA, Osaka (JP)

(21) Appl. No.: 13/254,796

(22) PCT Filed: Nov. 12, 2009
(86) PCT No.: PCT/JP2009/069279

§ 371 Date: Sep. 15, 2011

(30) Foreign Application Priority Data
Mar. 6, 2009 (JP) 2009-053739

(51) Int. Cl. H01L 31/12

(52) U.S. Cl. 257/84; 257/E33.077

(57) ABSTRACT

In a liquid crystal display apparatus (1) including a touch panel, a liquid crystal panel (display portion) (2) having a plurality of pixels, and a backlight device (backlight portion) (3) that irradiates the liquid crystal panel (2) with illumination light, the touch panel includes optical sensors (25) that are provided in pixel units and that detect infrared light. Furthermore, the backlight device (3) includes white light-emitting diodes (first light-emitting diode portion) (26) which can emit white light, infrared light-emitting diodes (second light-emitting diode portion) (27) which emit infrared light, and a substrate (28) on which the white light-emitting diodes (26) and the infrared light-emitting diodes (27) are integrally provided.

### TECHNICAL FIELD

The present invention relates to a display apparatus having touch panel functions that input operating instructions from the user, and more particularly to a display apparatus having built-in touch panel functions and optical sensors that detect infrared light.

### BACKGROUND ART

For recent mobile devices such as PDAs, portable phones, or notebook-type PCs, it is becoming mainstream to install a display apparatus equipped with a touch panel that can be operated by the touch of the screen by a finger, pen, or the like. With a mobile device of the aforementioned type, improvement in portability is generally sought by the use of a liquid crystal panel having such characteristics as a low profile and light weight for the display portion that performs information display. However, as it stands now, external types such as a resistive film system and capacitive system are mainstream for these touch panels, leaving the problems of a larger frame, increased thickness, and the like. Therefore, in place of external touch panels, active efforts have been made to develop a display apparatus of a type that incorporates touch panel functions within the display apparatus, which can be made thinner and have a narrower frame. Among these, a method in which a plurality of optical sensors are provided in the display panel, and an image shape created when a finger or the like approaches the screen is detected by the optical sensors is known as a method for detecting the touched positions within the display screen. In this image detection method, when the illuminance of the outside light is low (surroundings are dark), a distinction between the image shape and background becomes difficult within the image obtained by the optical sensors, so there are cases in which the touched positions cannot be detected accurately. In light of this, for a display apparatus equipped with a backlight device, a method is also known in which an image that is reflected when illumination light of the backlight device strikes a finger or pen is detected by optical sensors.

A conventional display apparatus that has built-in touch panel functions as described above is provided with, for each pixel provided in the display surface of the display portion (liquid crystal panel), a visible light-emitting cell that emits light of each of the colors of red (R), green (G), and blue (B) and a non-visible light-emitting cell that emits light in a non-visible light region as described in Patent Document 1 below, for example. In this conventional display apparatus, furthermore, a light-receiving element (optical sensor) that receives light in a non-visible light region is installed for each of the aforementioned pixels, and the configuration is such that the object of detection is detected based on light-receiving signals (detection results) of this light-receiving element. Then, because the light-receiving elements that receive light in a non-visible light region are used in this conventional display apparatus, even when black display, for instance, is performed in the display portion, the object of detection can be detected without depending upon the displayed image, thus making it possible to improve detection precision in the touch panel.

### RELATED ART DOCUMENTS

### Patent Documents

Patent Document 1: Japanese Patent Application Laid-Open Publication No. 2008-262204

### SUMMARY OF THE INVENTION

### Problems to be Solved by the Invention

However, with a conventional display apparatus as described above, when detection precision in the touch panel is improved, problems arise in that the pixel structure becomes complex and display performance is lowered.

In concrete terms, with the conventional display apparatus, non-visible light-emitting cells (infrared light-emitting regions) are configured by installing transmission filters that selectively transmit light in a non-visible light region from light in a visible light region (white light) and light in a non-visible light region (infrared light) that are contained in the light from the light source. For this reason, the problem of complicating the pixel structure arises with the conventional display apparatus. Furthermore, with the conventional display apparatus, an infrared light-emitting region as described above is formed within a pixel, so problems occur in that the resolution of the display portion (liquid crystal panel) is lowered, and that the display performance is also lowered.

There is no description regarding the structure of the light source portion with the conventional display apparatus, so when the surrounding environment becomes bright, a problem arises in that it becomes difficult to distinguish between the reflected image of the finger and the background caused by the surrounding light within the image obtained by the optical sensors. Specifically, the conventional display apparatus may sometimes create a problem in that adequate detection precision cannot be ensured due to the adverse effect of the surrounding environment.

Moreover, in order to make operation possible in a bright environment such as above, it is conceivable to increase the light intensity of the backlight device. However, in the case of using, as the light source, a backlight device installed with individualized-type light-emitting diodes, which is currently mainstream, a large number of light-emitting diodes needs to be installed, so a new problem arises in that it is difficult to make the display apparatus thinner and the frame narrower.

In light of the problems described above, the present invention has as its object to provide a display apparatus with a simple structure that can prevent display performance from lowering while ensuring sufficient detection precision regardless of the surrounding environment even when the detection precision in the touch panel is increased.

### Means for Solving the Problems

In order to achieve the aforementioned object, the display apparatus of the present invention is a display apparatus including a touch panel, a display portion having a plurality of pixels, and a backlight portion that irradiates the aforementioned display portion with illumination light, wherein

the aforementioned touch panel includes optical sensors that are provided in the aforementioned pixel units and that detect infrared light, and

the aforementioned backlight portion includes a first light-emitting diode portion which can emit white light, a second light-emitting diode portion which emits infrared light, and a substrate on which the aforementioned first and second light-emitting diode portions are integrally provided.

With the display apparatus configured as described above, because optical sensors that are provided in pixel units and that detect infrared light are included in the touch panel, the detection precision in this touch panel can be improved. Furthermore, the backlight portion includes a substrate on which the first light-emitting diode portion which can emit white light and the second light-emitting diode portion which emits infrared light are integrally provided. This makes it possible to obtain, in the aforementioned illumination light, an illumination light intensity required to obtain sufficient detection precision even in a bright environment and to make the respective luminance distributions of the white light and infrared light uniform. As a result, unlike the aforementioned conventional art, infrared light can be appropriately emitted toward the outside from the display portion without installing a transmission filter to provide a non-visible light-emitting cell (infrared light-emitting region) within a pixel. Accordingly, unlike the aforementioned prior art, it is possible to configure a display apparatus with a simple structure that can prevent a drop in display performance such as a drop in resolution while ensuring sufficient detection precision regardless of the surrounding environment even when the detection precision in the touch panel is increased.

Moreover, in the aforementioned display apparatus, the aforementioned first and second light-emitting diode portions may be provided alternately and linearly on the aforementioned substrate in the aforementioned backlight portion.

With this configuration, the respective luminance distributions of the white light and infrared light can be easily made uniform in the aforementioned illumination light, and the detection precision of the optical sensors can be improved.

In addition, in the aforementioned display apparatus, it is preferable that the aforementioned first light-emitting diode portion include a blue light-emitting element that is installed on the aforementioned substrate and that emits blue light and a fluorescent resin which is provided on the aforementioned substrate so as to seal the aforementioned blue light-emitting element and which emits the aforementioned white light by converting a portion of the aforementioned blue light into yellow light and mixing the aforementioned blue light and the aforementioned yellow light, and

that the aforementioned second light-emitting diode portion include an infrared light-emitting element that is installed on the aforementioned substrate and that emits the aforementioned infrared light and a transparent resin that is provided on the aforementioned substrate so as to seal the aforementioned infrared light-emitting element.

This configuration makes it possible to obtain white light with the blue light-emitting element and the fluorescent resin and to obtain infrared light with the infrared light-emitting elements. Furthermore, because there is involved no packaging of each of the first and second light-emitting diode portions, a larger number of light-emitting diodes can be mounted in a limited space, so the backlight portion can be reduced in size. Accordingly, it is possible to make the backlight portion thinner and the frame of the display apparatus narrower.

Moreover, in the aforementioned display apparatus, a plurality of the aforementioned infrared light-emitting elements are sealed by the aforementioned transparent resin on the aforementioned substrate in the aforementioned second light-emitting diode portion.

With this configuration, because there is involved no packaging of the second light-emitting diode portion, a larger number of light-emitting diodes can be mounted in a limited space, which allows the size of the backlight portion to be reduced. Accordingly, the intensity of the infrared light can be increased while making the backlight portion thinner and the frame of the display apparatus narrower.

In addition, in the aforementioned display apparatus, a blue light-emitting element that is included in the aforementioned first light-emitting diode portion and that emits blue light and an infrared light-emitting element that is included in the aforementioned second light-emitting diode portion and that emits infrared light may be installed on the aforementioned substrate in the aforementioned backlight portion, and

this backlight portion may be provided with a fluorescent resin which is provided on the aforementioned substrate so as to seal the aforementioned blue light-emitting element and the aforementioned infrared light-emitting element and which emits the aforementioned white light by converting a portion of the aforementioned blue light into yellow light and mixing the aforementioned blue light and the aforementioned yellow light.

With this configuration, the manufacturing yield of the backlight portion can be improved easily, so the cost of the display apparatus can be easily reduced.

Furthermore, in the aforementioned display apparatus, it is preferable that the aforementioned backlight portion include a light guide plate, and

that the aforementioned first and second light-emitting diode portions be disposed so as to face at least one side surface of the aforementioned light guide plate in the aforementioned backlight portion.

This configuration makes it possible to easily achieve a lower profile of the display apparatus.

Moreover, in the aforementioned display apparatus, the aforementioned first and second light-emitting diode portions may be disposed so as to face each of the two mutually opposing side surfaces of the aforementioned light guide plate in the aforementioned backlight portion.

With this configuration, it is possible to easily obtain favorable uniformity of the white light required for image display and of the infrared light required for the detection of the object of detection in the aforementioned illumination light.

In addition, in the aforementioned display apparatus, it is preferable that a liquid crystal panel be used for the aforementioned display portion, and

that the aforementioned optical sensors be provided integrally on the active matrix substrate of the aforementioned liquid crystal panel.

This configuration makes it possible to easily configure a compact display apparatus equipped with a touch panel.

### Effects of the Invention

The present invention makes it possible to provide a display apparatus with a simple structure that can prevent display performance from lowering while ensuring sufficient detection precision regardless of the surrounding environment even when the detection precision in the touch panel is increased.

### BRIEF DESCRIPTION OF THE DRAWINGS

FIG. 1 is a schematic sectional view illustrating a liquid crystal display apparatus according to a first embodiment of the present invention.

FIG. 2 is a diagram illustrating a configuration of essential parts of the aforementioned liquid crystal display apparatus.

FIG. 3 is an enlarged sectional view showing a concrete pixel structure of the aforementioned liquid crystal display apparatus.

FIG. 4 is an equivalent circuit diagram showing the configuration of the pixels and optical sensors provided in the aforementioned liquid crystal display apparatus.

FIG. 5 is a perspective view showing a concrete configuration of the linear light-emitting diode unit shown in FIG. 1.

FIG. 6 is a block diagram showing an example of a concrete configuration of the backlight control portion shown FIG. 2.

FIG. 7 is a block diagram showing an example of a concrete configuration of the signal processing portion shown FIG. 2.

FIG. 8 is a diagram illustrating a linear light-emitting diode unit in a liquid crystal display apparatus according to a second embodiment of the present invention; FIG. 8(a) is a perspective view of this linear light-emitting diode unit, and FIG. 8(b) is a plan view showing the configuration of essential parts of this linear light-emitting diode unit.

FIG. 9 is a schematic sectional view illustrating a liquid crystal display apparatus according to a third embodiment of the present invention.

FIG. 10 is a schematic sectional view illustrating a liquid crystal display apparatus according to a fourth embodiment of the present invention.

FIG. 11(a) is a plan view showing an example of arrangement of the light-emitting diode units shown in FIG. 10, and FIG. 11(b) is a diagram illustrating an example of a concrete configuration of the aforementioned light-emitting diodes.

### DETAILED DESCRIPTION OF EMBODIMENTS

Preferred embodiments of a display apparatus of the present invention will be described below with reference to the figures. Note that the following description is given by exemplifying a case in which the present invention is applied to a liquid crystal display apparatus equipped with an edge-light-type backlight device. Furthermore, the dimensions of the structural members in each figure are not faithful representations of the dimensions of actual structural members, the dimensional ratios of the respective structural members, and the like.

### First Embodiment

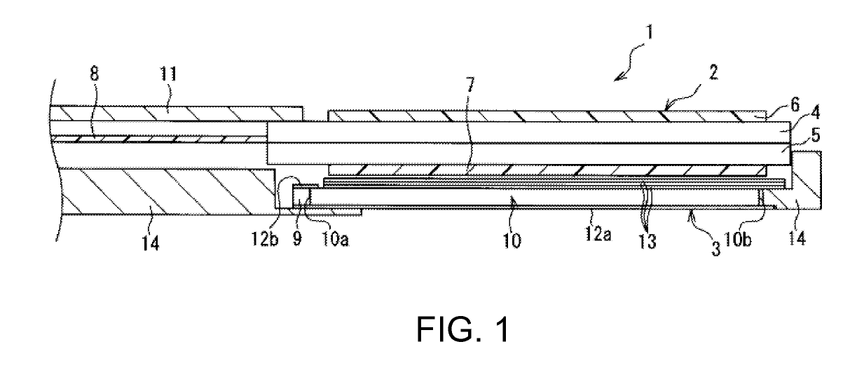

FIG. 1 is a schematic sectional view illustrating a liquid crystal display apparatus according to a first embodiment of the present invention. In FIG. 1, a liquid crystal display apparatus 1 of the present embodiment is provided with a liquid crystal panel 2 as a display portion that is installed with the upper side of FIG. 1 being taken as the viewing side (display surface side) and a backlight device 3 as a backlight portion that is disposed on the non-display surface side (lower side in FIG. 1) of the liquid crystal panel 2 and that irradiates this liquid crystal panel 2 with illumination light. Moreover, this liquid crystal display apparatus 1 has an integrated touch panel equipped with optical sensors (to be described later), so the liquid crystal display apparatus 1 is constructed such that this touch panel makes it possible to execute specified touch panel functions such as a user-operated input instruction detection action.

The liquid crystal panel 2 includes a color filter substrate 4 and an active matrix substrate 5 that constitute a pair of substrates, along with polarizing plates 6 and 7 that are respectively provided on the respective outside surfaces of the color filter substrate 4 and active matrix substrate 5. A liquid crystal layer (to be described later) is sandwiched between the color filter substrate 4 and the active matrix substrate 5. The polarizing plates 6 and 7 are each affixed to the corresponding color filter substrate 4 and active matrix substrate 5 so as to cover at least the effective display region of the display surface provided in the liquid crystal panel 2.

In addition, the active matrix substrate 5 constitutes one of the substrates in the aforementioned pair of substrates, and on the active matrix substrate 5, pixel electrodes, thin-film transistors (TFTs), and the like are formed between this active matrix substrate 5 and the aforementioned liquid crystal layer so as to correspond to a plurality of pixels contained in the display surface of the liquid crystal panel 2 (details are to be described later). Meanwhile, the color filter substrate 4 constitutes the other of the substrates in the aforementioned pair of substrates, and on the color filter substrate 4, color filters (to be described later), an opposite electrode, and the like are formed between this color filter substrate 4 and the aforementioned liquid crystal layer.

Furthermore, the liquid crystal panel 2 is provided with a flexible printed circuit (FPC) 8 connected to a control device (not shown in the figure) that performs the drive control of this liquid crystal panel 2, so a desired image is displayed on this display surface by the action of the aforementioned liquid crystal layer in pixel units.

The backlight device 3 includes a linear light-emitting diode unit 9 as the light source and a light guide plate 10 disposed facing the linear light-emitting diode unit 9. As will be described in detail later, this linear light-emitting diode unit 9 is provided with white light-emitting diodes (first light-emitting diode portion) which emit white light and infrared light-emitting diodes (second light-emitting diode portion) which emit infrared light, so the white light used for information display and the infrared light detected by the aforementioned optical sensors and used for the touch panel functions are incident on the side of the liquid crystal panel 2 via the light guide plate 10.

Moreover, with the backlight device 3, a bezel 14 with an L-shaped cross section holds the linear light-emitting diode unit 9 and the light guide plate 10 in a state in which the liquid crystal panel 2 is installed over the light guide plate 10. In addition, a case 11 is mounted on the color filter substrate 4. Thus, the backlight device 3 is assembled with the liquid crystal panel 2 and unified as a transmissive-type liquid crystal display apparatus 1 in which illumination light from this backlight device 3 is incident on the liquid crystal panel 2.

A synthetic resin such as a transparent polycarbonate resin, for instance, is used for the light guide plate 10, and light from the linear light-emitting diode unit 9 enters the light guide plate 10. In concrete terms, a planar plate is used for the light guide plate 10 as shown by example in FIG. 1, and the light guide plate 10 includes mutually opposing side surfaces 10a and 10b. In addition, in the present embodiment, the linear light-emitting diode unit 9 is disposed so as to face the side surface 10a of the light guide plate 10, so this side surface 10a functions as the light entry surface through which light from the linear light-emitting diode unit 9 enters.

Furthermore, a reflective sheet 12a is installed on the surface of the light guide plate 10 on the side opposite from this liquid crystal panel 2. This reflective sheet 12a is disposed so as to reach underneath the linear light-emitting diode unit 9 and is constructed, together with a reflective sheet 12b installed above the linear light-emitting diode unit 9, such that light from the linear light-emitting diode unit 9 is efficiently caused to enter the interior of the light guide plate 10. Moreover, optical sheets 13, such as a lens sheet and a diffusion sheet, are provided on the light guide plate 10 on the side of the liquid crystal panel 2, so light emitted from the light guide plate 10 is applied to the liquid crystal panel 2 after changing the light path thereof in the direction of the front surface and being altered to the planar illumination light that has desired viewing-angle characteristics and that has an uniform intensity within the light-emission surface.

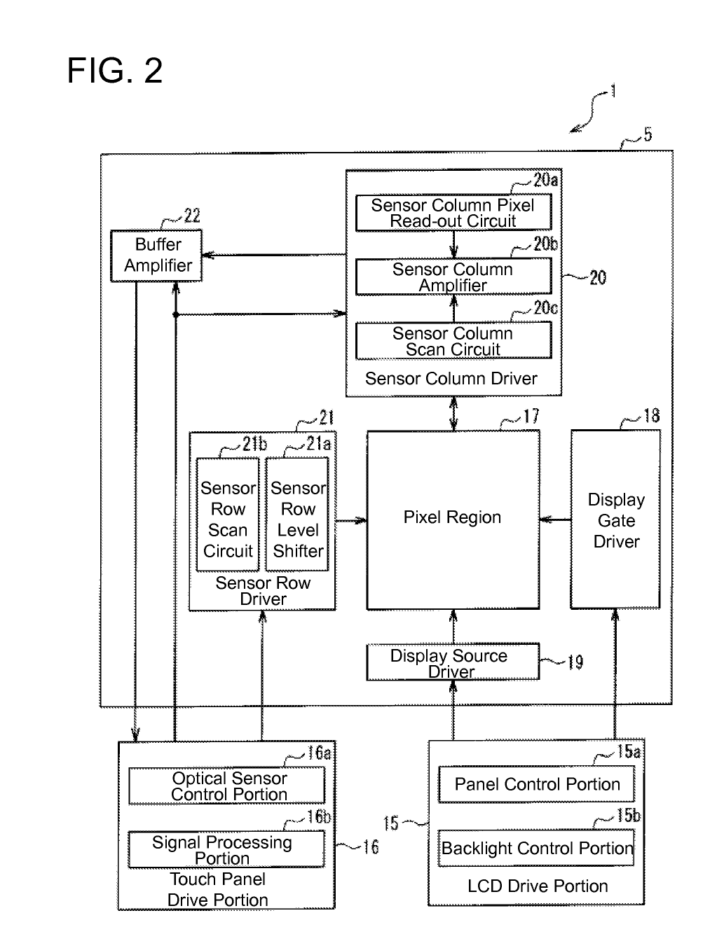

Next, each component of the liquid crystal display apparatus 1 of the present embodiment will be described in concrete terms with reference to FIGS. 2 to 7 as well.

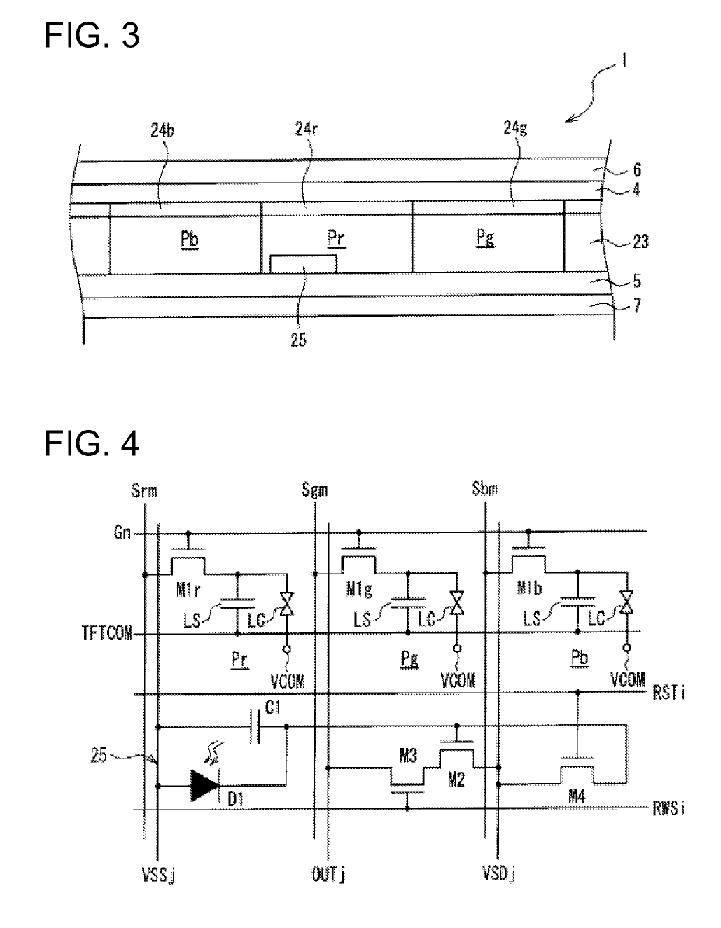

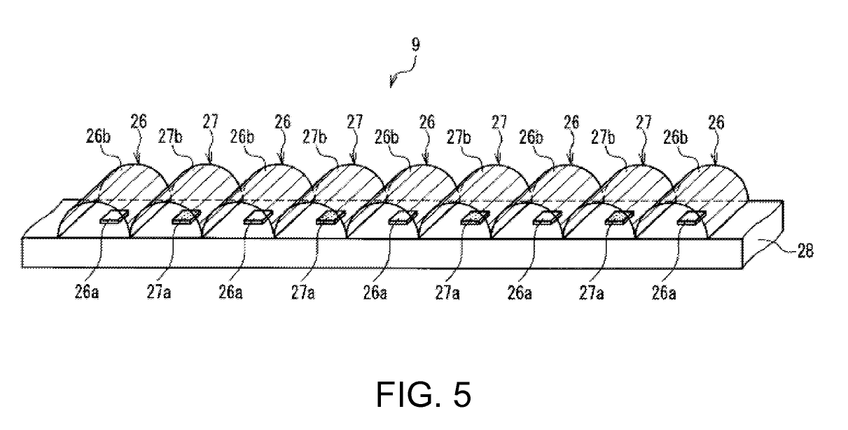

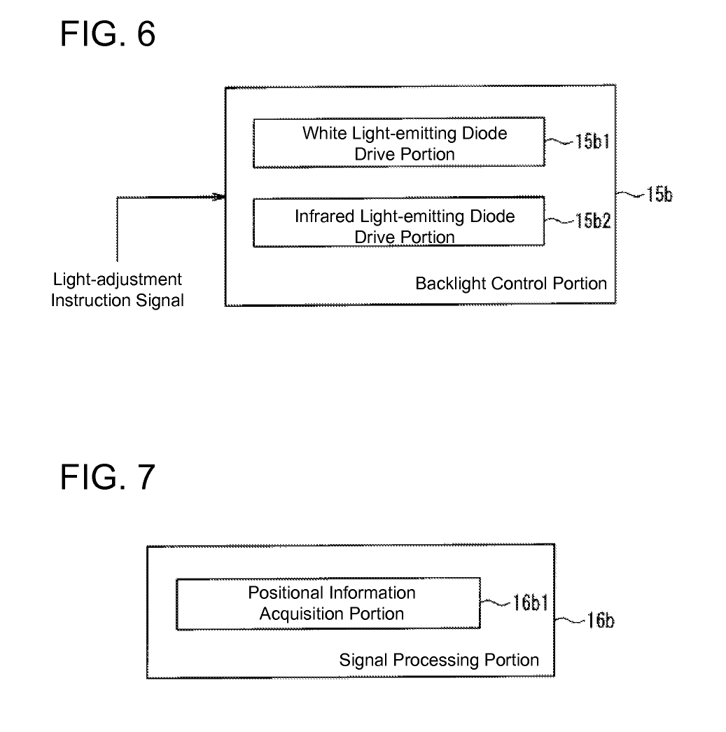

FIG. 2 is a diagram illustrating a configuration of essential parts of the aforementioned liquid crystal display apparatus, and FIG. 3 is an enlarged sectional view showing a concrete pixel structure of the aforementioned liquid crystal display apparatus. FIG. 4 is an equivalent circuit diagram showing a configuration of the pixels and optical sensors provided in the aforementioned liquid crystal display apparatus, and FIG. 5 is a perspective view showing a concrete configuration of the linear light-emitting diode unit shown in FIG. 1. FIG. 6 is a block diagram showing an example of a concrete configuration of the backlight control portion shown in FIG. 2, and FIG. 7 is a block diagram showing an example of a concrete configuration of the signal processing portion shown in FIG. 2.

As is exemplified in FIG. 2, with the liquid crystal display apparatus 1 of the present embodiment, a pixel region 17, a display gate driver 18, a display source driver 19, a sensor column driver 20, a sensor row driver 21, and a buffer amplifier 22 are provided on the active matrix substrate 5. The display gate driver 18 and display source driver 19 are connected to an LCD drive portion 15 via a flexible printed circuit (FPC) which is not shown in the figures, and the sensor column driver 20, sensor row driver 21, and buffer amplifier 22 are connected to a touch panel drive portion 16 via another FPC (not shown in the figures).

Note that the aforementioned structural members on the active matrix substrate 5 can also be formed monolithically on a transparent substrate such as a transparent glass substrate that constitutes this active matrix substrate 5 by means of semiconductor process. Alternatively, drivers or the like among the aforementioned structural members may also be mounted on the aforementioned transparent substrate by chip-on-glass (COG) technology or the like, for example.

In addition, besides the aforementioned description, it would also be possible to interpose the same FPC to connect the display gate driver 18 and display source driver 19 to the LCD drive portion 15 and to connect the sensor column driver 20, sensor row driver 21, and buffer amplifier 22 to the touch panel drive portion 16.

The pixel region 17 constitutes the display surface of the aforementioned liquid crystal panel 2, with a plurality of pixels being provided in a matrix. Furthermore, the aforementioned optical sensors are provided on the pixel region 17 in pixel units.

In concrete terms, with the liquid crystal panel 2, as is exemplified in FIG. 3, red (R), green (G), and blue (B) color filters 24r, 24g, and 24b are formed on the surface of the color filter substrate 4 on the side of the liquid crystal layer 23. With the liquid crystal panel 2, furthermore, pixels Pr, Pg, and Pb of the respective RGB colors are provided so as to correspond to the respective color filters 24r, 24g, and 24b.

Meanwhile, on the active matrix substrate 5, a switching element (to be described later) is formed for each pixel. On the active matrix substrate 5, furthermore, the aforementioned optical sensors 25 are provided in an integrated manner with the aforementioned switching elements. Moreover, as shown in FIG. 3, the light-receiving element of the optical sensors 25 is disposed in the pixel Pr, for example, among the pixels Pr, Pg, and Pb in order to receive infrared light that is incident from the outside of the aforementioned display surface. In addition, these optical sensors 25 are designed to detect infrared light contained in the aforementioned illumination light.

Furthermore, the aforementioned touch panel is designed such that with the optical sensors 25 receiving infrared light reflected from a reflective object (object of detection) such as a finger, the optical sensors 25 perform a coordinate detection action to detect the coordinates (position) indicated by the touch operation or the like of a user. Then, the touch panel uses the results of the coordinate detection action to perform specified touch panel functions such as a user-operated input instruction detection action (details are to be described later).

Moreover, as is shown in FIG. 4, gate lines Gn and source lines Srm, Sgm, and Sbm are disposed in a matrix in the pixel region 17 as wiring for the pixels. The gate lines Gn are connected to the display gate driver 18. The source lines Srm, Sgm, and Sbm are provided for the respective RGB colors and are connected to the display source driver 19.

Thin-film transistors (TFTs) M1r, M1g, and M1b as the aforementioned switching elements for the pixels are respectively provided at the intersections between the gate line Gn and the source lines Srm, Sgm, and Sbm. In the pixel Pr, the gate electrode of the thin-film transistor M1r is connected to the gate line Gn, while the source electrode is connected to the source line Srm, and the drain electrode is connected to a pixel electrode that is not shown in the figures. Consequently, in the pixel Pr, a liquid crystal capacitance LC is formed between the drain electrode of the thin-film transistor M1r and an opposite electrode (VCOM) as shown in FIG. 4. In addition, an auxiliary capacitance LS is formed in parallel to the liquid crystal capacitance LC.

Similarly, in the pixel Pg, the gate electrode of the thin-film transistor M1g is connected to the gate line Gn, while the source electrode is connected to the source line Sgm, and the drain electrode is connected to a pixel electrode that is not shown in the figures. Consequently, in the pixel Pg, a liquid crystal capacitance LC is formed between the drain electrode of the thin-film transistor M1g and an opposite electrode (VCOM) as shown in FIG. 4. Furthermore, an auxiliary capacitance LS is formed in parallel to the liquid crystal capacitance LC.

Moreover, in the pixel Pb, the gate electrode of the thin-film transistor M1b is connected to the gate line Gn, while the source electrode is connected to the source line Sbm, and the drain electrode is connected to a pixel electrode that is not shown in the figures. Consequently, in the pixel Pb, a liquid crystal capacitance LC is formed between the drain electrode of the thin-film transistor M1b and an opposite electrode (VCOM) as shown in FIG. 4. In addition, an auxiliary capacitance LS is formed in parallel to the liquid crystal capacitance LC.

Furthermore, the respective pixels Pr, Pg, and Pb are designed such that a voltage signal (gradation voltage) in accordance with the luminance (gradation) of the information to be displayed on the aforementioned display surface is supplied from the display source driver 19 via the corresponding source lines Srm, Sgm, and Sbm.

Specifically, as shown in FIG. 2, a panel control portion 15a and a backlight control portion 15b are provided in the LCD drive portion 15. The panel control portion 15a is configured such that image signals for the information to be displayed on the aforementioned display surface are input thereto from outside the liquid crystal display apparatus 1. Moreover, in the panel control portion 15a, instruction signals to each of the display gate driver 18 and the display source driver 19 are generated in accordance with the input image signals and are outputted.

On the basis of the instructions signals from the panel control portion 15a, the display gate driver 18 sequentially outputs, to the plurality of gate lines Gn arranged in a matrix, gate signals that will turn the gate electrodes of the corresponding thin film transistors M1r, M1g, and M1b to the ON state. Meanwhile, the display source driver 19 supplies the aforementioned gradation voltages to the respective pixels Pr, Pg, and Pb via the corresponding source lines Srm, Sgm, and Sbm on the basis of the instructions signals from the panel control portion 15a.

In addition, the backlight control portion 15b is configured such that light-adjustment instructions signals that give instructions to change the luminance of the aforementioned illumination light are input thereto from controllers or the like provided on the liquid crystal display apparatus 1. Moreover, the backlight control portion 15b is constructed such that the power supplied to the linear light-emitting diode unit 9 of the backlight device 3 is controlled on the basis of the input of the light-adjustment instruction signals.

Here, the linear light-emitting diode unit 9 is concretely described with reference to FIG. 5.

As is shown in FIG. 5, in the linear light-emitting diode unit 9 of the present embodiment, a plurality of (e.g., five) white light-emitting diodes 26 and a plurality of (e.g., four) infrared light-emitting diodes 27 are provided integrally on a substrate 28. In the linear light-emitting diode unit 9, furthermore, the white light-emitting diodes 26 and infrared light-emitting diodes 27 are provided alternately and linearly on the substrate 28 as shown in FIG. 5.

The white light-emitting diodes 26 constitute a first light-emitting diode portion that emits white light used for information display in the liquid crystal panel 2. Moreover, each of the white light-emitting diodes 26 includes a blue light-emitting element 26a that is installed on the substrate 28 and that emits blue light and a fluorescent resin 26b that is provided on the substrate 28 so as to seal the blue light-emitting element 26a and that emits white light by converting a portion of the blue light into yellow light and mixing the blue light and the yellow light.

In the blue light-emitting element 26a, the electrode terminal thereof is electrically connected to wiring provided on the substrate 28 (not shown in the figure). In addition, as is exemplified in FIG. 5, the fluorescent resin 26b is constructed in a substantially semicircular column shape and is designed to protect the sealed blue light-emitting element 26a and to improve the directional characteristics of white light emitted to the outside.

The infrared light-emitting diodes 27 constitute a second light-emitting diode portion that emits infrared light to be detected by the optical sensors 25. Furthermore, each of these infrared light-emitting diodes 27 includes an infrared light-emitting element 27a that is installed on the substrate 28 and that emits infrared light of a wavelength (e.g., 850 nm) in a specified range (e.g., 800 nm to 950 nm) and a transparent resin 27b provided on the substrate 28 so as to seal the infrared light-emitting element 27a.

In the infrared light-emitting element 27a, as in the blue light-emitting element 26a, the electrode terminal thereof is electrically connected to wiring provided on the substrate 28 (not shown in the figure). Furthermore, as is exemplified in FIG. 5, the transparent resin 27b is constructed in a substantially semicircular column shape and is designed to protect the sealed infrared light-emitting element 27a and to improve the directional characteristics of infrared light emitted to the outside.

Moreover, in the linear light-emitting diode unit 9, the blue light-emitting elements 26a and the infrared light-emitting elements 27a are mounted on the substrate 28 at a specified distance apart from each other, and each of these blue light-emitting elements 26a and infrared light-emitting elements 27a is connected to a power supply circuit via the aforementioned wiring and FPC so that power is supplied thereto (not shown in the figure). In addition, in the linear light-emitting diode unit 9, the white light-emitting diodes 26 and the infrared light-emitting diodes 27 are provided integrally on the substrate 28 such that the fluorescent resin 26b and transparent resin 27b make close contact.

Note that in the linear light-emitting diode unit 9, the reflective sheets 12a and 12b are respectively in contact with the upper end surfaces and the lower end surfaces of the substantially semicircular column-shaped fluorescent resin 26b and transparent resin 26b so that the white light from the white light-emitting diodes 26 and the infrared light from the infrared light-emitting diodes 27 are caused to be incident into the light guide plate 10 without leaking to the outside.

Thus, in the linear light-emitting diode unit 9, the white light-emitting diodes 26 and the infrared light-emitting diodes 27 are disposed in a mixed manner on the substrate 28, and they are disposed with equally allocated spacing with respect to the display region (the display surface of the liquid crystal panel 2). Therefore, in the aforementioned planar illumination light that irradiates the side of the liquid crystal panel 2 from the backlight device 3, the in-plane luminance distribution can be made to be uniform for each of the white light and the infrared light. Note that if the white light-emitting diodes 26 and the infrared light-emitting diodes 27 are respectively disposed on separate substrates, for example, and if the corresponding white light and infrared light are caused to be incident on the light guide plate 10 from different side surfaces of this light guide plate 10, it would be difficult to make the in-plane luminance distribution uniform for both the white light and infrared light. Furthermore, when the in-plane luminance distribution of the infrared light is thus non-uniform, the detection precision of the touch panel may drop in some cases.

Moreover, in the linear light-emitting diode unit 9, the white light-emitting diodes 26 and the infrared light-emitting diodes 27 are integrally provided on the substrate 28 such that the blue light-emitting elements 26a and the infrared light-emitting elements 27a are mounted on the substrate 28 at a specified distance apart from each other and such that the fluorescent resin 26b and transparent resin 27b make close contact with each other as described above. Therefore, in the linear light-emitting diode unit 9, compared to a case in which individualized white light-emitting diodes and infrared light-emitting diodes, which are constructed separately from each other, are placed on a flexible substrate (substrate), the respective numbers of the white light-emitting diodes 26 and infrared light-emitting diodes 27 to be installed can be increased with ease, thus making it possible to easily enhance the luminance of the white light and the intensity of the infrared light.

In addition, as shown in FIG. 6, the backlight control portion 15b is provided with a white light-emitting diode drive portion 15b1 that performs the drive control of each of the five white light-emitting diodes 26 and an infrared light-emitting diode drive portion 15b2 that performs the drive control of each of the four infrared light-emitting diodes 27. The white light-emitting diode drive portion 15b1 determines the power supplied to each of the white light-emitting diodes 26 based on the aforementioned light-adjustment instructions signals and causes a lighting action of each of the white light-emitting diodes 26. Furthermore, the infrared light-emitting diode drive portion 15b2 causes a lighting action of each of the infrared light-emitting diodes 27 such that infrared light of a specified intensity is emitted from each of the infrared light-emitting diodes 27.

Returning to FIG. 4, the optical sensor 25 includes a photodiode D1 as the aforementioned light-receiving element, a capacitor C1, and thin-film transistors M2 to M4. Moreover, the optical sensor 25 is configured such that a constant voltage is supplied from the sensor column driver 20 via wiring VSSj and VSDj provided in parallel to the source lines Srm and Sbm, respectively. In addition, the optical sensor 25 is constructed such that the detection results are output to the sensor column pixel read-out circuit 20a of the sensor column driver 20 via wiring OUTj provided in parallel to the source line Sgm.

Furthermore, wiring RSTi for supplying a reset signal is connected to the thin-film transistor M4. Wiring RWSi for supplying a read-out signal is connected to the thin-film transistor M3. Such wiring RSTi and RWSi are connected to the sensor row driver 21.

The sensor column driver 20 includes a sensor column pixel read-out circuit 20a, a sensor column amplifier 20b, and a sensor column scan circuit 20c as shown in FIG. 2 and is designed to act in accordance with the instructions signals from the optical sensor control portion 16a of the touch panel drive portion 16. The sensor column pixel read-out circuit 20a is configured such that the detection results (voltage signals) of each of the plurality of optical sensors 25 provided in a matrix within the pixel region 17 are successively input thereto via the wiring OUTj. Then, the sensor column pixel read-out circuit 20a outputs the input voltage signals to the sensor column amplifier 20b.

The sensor column amplifier 20b has a plurality of built-in amplifiers (not shown in the figures) that are provided so as to correspond to the plurality of optical sensors 25 and amplifies the aforementioned corresponding voltage signals and outputs them to the buffer amplifier 22. The sensor column scan circuit 20c outputs, to the sensor column amplifier 20b in accordance with the instruction signals from the optical sensor control portion 16a, column select signals for sequentially connecting the plurality of amplifiers of the sensor column amplifier 20b to the buffer amplifier 22. Consequently, the amplified voltage signals are output from the sensor column amplifier 20b to the touch panel drive portion 16 via the buffer amplifier 22.

The sensor row driver 21 is provided with a sensor row level shifter 21a using a shift register and a sensor row scan circuit 21b. The sensor row scan circuit 21b sequentially selects the wiring RSTi and RWSi at a specified time interval in accordance with the instructions signals from the optical sensor control portion 16a. Consequently, in the pixel region 17, the optical sensors 25 from which the voltage signals (detection results) are read out are sequentially selected row by row in the matrix.

Note that the aforementioned description involves a case in which a single optical sensor 25 is provided for a set of pixels Pr, Pg, and Pb of RGB in the pixel region 17. However, the number of the optical sensors 25 to be installed in the pixel region 17, the arrangement locations of the structural members such as the photodiodes D1 included therein, and the like can be modified as needed without being limited to those described above. For instance, a configuration is also possible in which a photodiode (light-receiving element) D1 that substantively performs optical detection is provided for each of the pixels Pr, Pg, and Pb, and an optical sensor 25 is installed for each pixel.

As shown in FIG. 2, the touch panel drive portion 16 is provided with an optical sensor control portion 16a and a signal processing portion 16b. Moreover, this touch panel drive portion 16 is designed to perform the drive control of each of the plurality of optical sensors 25 and to perform specified touch panel functions such as the detection of operated input instructions by the touch operation of the user on the basis of the respective detection results of the plurality of optical sensors 25.

The optical sensor control portion 16a outputs drive instruction signals to the sensor column driver 20 and the sensor row driver 21 to cause the optical sensors 25 to perform a sensing action when the power of the liquid crystal display apparatus 1 is switched on, for example. Specifically, the optical sensor control portion 16a is designed to detect a touch operation by the user by causing the optical sensors 25 to perform the coordinate detection action when the liquid crystal display apparatus 1 is active. Moreover, the detection results of the optical sensors 25 are stored in a memory (not shown in the figures) provided inside the touch panel drive portion 16.

In addition, as shown in FIG. 7, the signal processing portion 16b is provided with a positional information acquisition portion 16b1, thus executing specified touch panel functions including a user-operated input instruction detection action.

Specifically, the positional information acquisition portion 16b1 uses the detection results of the optical sensors 25 (i.e., the results of the coordinate detection action) stored in the aforementioned memory to acquire positional (coordinate) information of a user's finger or the like on the display surface of the aforementioned liquid crystal panel. Specifically, with the liquid crystal display apparatus 1 of the present embodiment, in cases where the user performs a touch operation by using a finger, for example, if the user places a finger on a desired position of (for example) an operation input screen (instruction input screen) displayed on the liquid crystal panel 2, infrared light emitted from the side of the liquid crystal panel 2 is reflected toward the liquid crystal panel 2 by this finger, and this reflected infrared light is detected by the optical sensors 25 in the vicinity of the area directly underneath that position. Then, the positional information acquisition portion 16b1 uses the detection results of the optical sensors 25 stored in the aforementioned memory to acquire the positional information of the touch operation position by the user on the instruction input screen. Thereby, a user-operated input instruction detection action is performed in the liquid crystal display apparatus 1 of the present embodiment.

Note that besides the aforementioned description, it would also be possible to have a configuration such that a scanning action that takes in image information is performed by the touch panel.

Furthermore, the touch panel drive portion 16, sensor column driver 20, sensor row driver 21, buffer amplifier 22, and optical sensors 25 are incorporated into the liquid crystal display apparatus 1 of the present embodiment to constitute a touch panel that performs prescribed touch panel functions.

With the liquid crystal display apparatus 1 of the present embodiment configured as above, the optical sensors 25 that are provided in pixel units and that detect infrared light reflected from the object of detection are included in the aforementioned touch panel, so the detection precision in this touch panel can be increased. Moreover, the backlight device (backlight portion) 3 includes the substrate 28 on which the white light-emitting diodes (first light-emitting diode portion) 26 for emitting white light and the infrared light-emitting diodes (second light-emitting diode portion) 27 for emitting infrared light are integrally provided. Consequently, the respective luminance distributions of the white light and infrared light can be made uniform in the aforementioned illumination light. As a result, with the liquid crystal display apparatus 1 of the present embodiment, unlike the aforementioned conventional art, infrared light can be emitted appropriately from the liquid crystal panel (display portion) 2 toward the outside without any need to install a transmission filter for providing a non-visible light-emitting cell (infrared light-emitting region) within a pixel. Accordingly, with the present embodiment, unlike the aforementioned conventional art, detection in a bright environment becomes possible even when the detection precision on the touch panel is increased. That is, with the present embodiment, sufficient detection precision can be ensured regardless of the surrounding environment. With the present embodiment, furthermore, a region that contributes to information display need not be reduced in the liquid crystal panel 2, thereby providing a structurally simple liquid crystal display apparatus 1 that can prevent a decrease in the display performance.

In addition, with the present embodiment, the white light-emitting diodes 26 and infrared light-emitting diodes 27 are provided alternately and linearly on the substrate 28 in the linear light-emitting diode unit 9. Consequently, with the liquid crystal display apparatus 1 of the present embodiment, the respective luminance distributions of the white light and infrared light can be made uniform easily in the aforementioned illumination light, so the detection precision of the optical sensors 25 can be improved.

### Second Embodiment

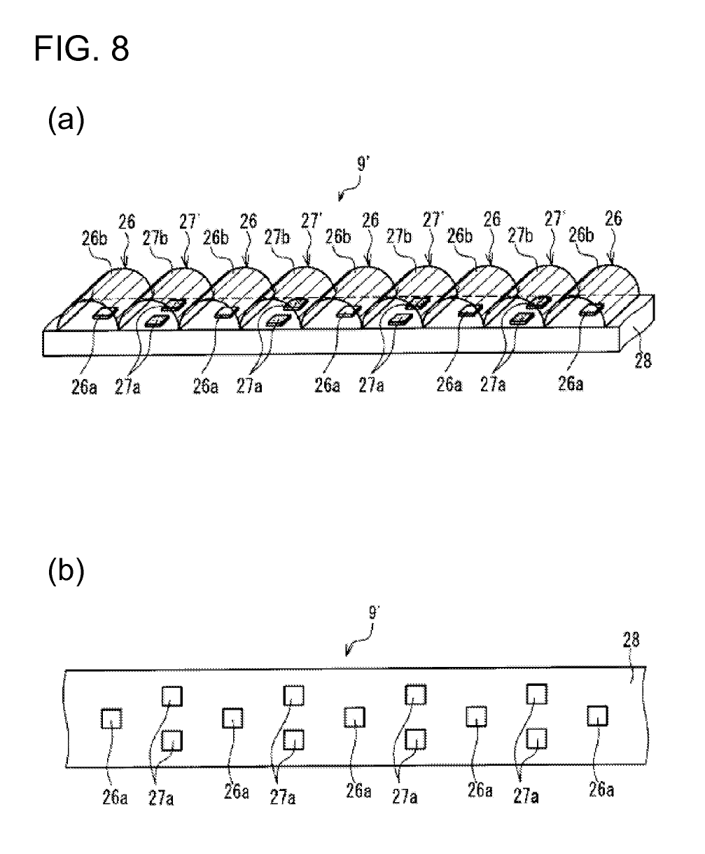

FIG. 8 is a diagram illustrating a linear light-emitting diode unit in a liquid crystal display apparatus according to a second embodiment of the present invention; FIG. 8(a) is a perspective view of this linear light-emitting diode unit, and FIG. 8(b) is a plan view showing a configuration of essential parts of this linear light-emitting diode unit. In the figures, the main difference between the present embodiment and the aforementioned first embodiment is that two infrared light-emitting elements are sealed by a transparent resin on the substrate. Note that the elements that are in common with the aforementioned first embodiment are labeled with the same reference characters, and a redundant description thereof will be omitted.

Specifically, as exemplified in FIGS. 8(a) and 8(b), in the linear light-emitting diode unit 9′ of the present embodiment, five white light-emitting diodes 26 and four infrared light-emitting diodes 27′ are integrally provided on the substrate 28. In the linear light-emitting diode unit 9′, furthermore, as in the first embodiment, the white light-emitting diodes 26 and the infrared light-emitting diodes 27′ are provided alternately and linearly on the substrate 28.

Moreover, in each of the infrared light-emitting diodes (second light-emitting diode portion) 27′, a plurality of (e.g., two) infrared light-emitting elements 27a are mounted on the substrate 28 in a state in which these are lined up along the up-down direction in FIG. 8(b). A transparent resin 27b is provided on the substrate 28 so as to seal the two infrared light-emitting elements 27a together in each of the infrared light-emitting diodes 27′.

As a result of the configuration above, the present embodiment makes it possible to manifest operations and effects similar to those of the aforementioned first embodiment. In addition, with the liquid crystal display apparatus 1 of the present embodiment, two infrared light-emitting elements 27a are sealed by a transparent resin 27b on the substrate 28 in each of the infrared light-emitting diodes (second light-emitting diode portion) 27′. That is, in the present embodiment, because there is no packaging of the second light-emitting diode portion, a larger number of light-emitting diodes can be mounted in a limited space, thus allowing the size of the backlight device (backlight portion) 3 to be reduced. Consequently, with the liquid crystal display apparatus 1 of the present embodiment, the intensity of the infrared light can be increased without increasing the frame of the liquid crystal panel 2 while also lowering the profile of the backlight device 3.

Specifically, with the liquid crystal display apparatus 1 of the present embodiment, compared to a case in which two of the linear light-emitting diode unit 9 shown in the first embodiment would need to be disposed in two tiers in the up-down direction in FIG. 8(b), the dimension in this up-down direction can be reduced, so the backlight device 3 can be made thinner. Furthermore, because the number of the installed blue light-emitting elements 26a for white light is not increased, the intensity of the infrared light can be increased while avoiding an unnecessary increase in cost. Moreover, because the intensity of the infrared light can be increased in this manner with the liquid crystal display apparatus 1 of the present embodiment, even under an environment where outside light such as sunlight is intense, it is possible to easily improve the detection precision of the optical sensors 25 and to easily enhance the touch panel functions in the touch panel as well, compared to the display apparatus of the first embodiment.

### Third Embodiment

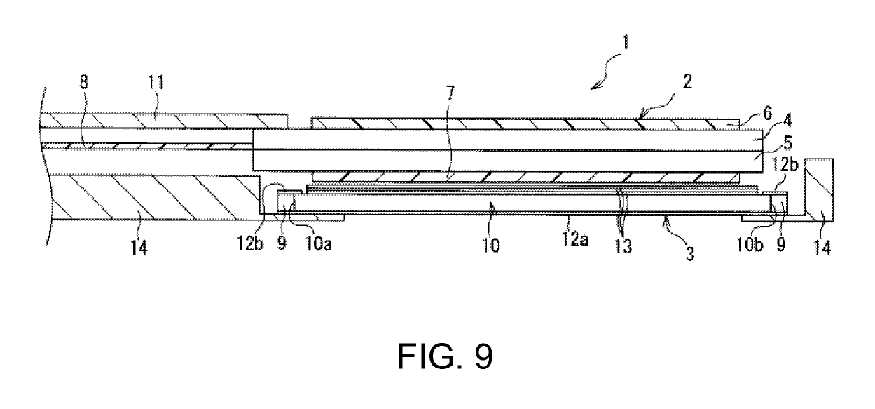

FIG. 9 is a schematic sectional view illustrating a liquid crystal display apparatus according to a third embodiment of the present invention. In the figure, the main difference between the present embodiment and the aforementioned first embodiment is that the linear light-emitting diode unit is disposed to each of the two mutually opposing side surfaces of the light guide plate. Note that the elements that are in common with the aforementioned first embodiment are labeled with the same reference characters, and a redundant description thereof will be omitted.

Specifically, as shown in FIG. 9, two linear light-emitting diode units 9 are disposed so as to respectively face the two mutually opposing side surfaces 10a and 10b of the light guide plate 10 in the liquid crystal display apparatus 1 of the present embodiment. With the liquid crystal display apparatus 1 of the present embodiment, white light from the white light-emitting diodes 26 and infrared light from the infrared light-emitting diodes 27 of the linear light-emitting diode unit 9 that faces the side surface 10a enter this side surface 10a, and such white light and infrared light are progressively emitted toward the liquid crystal panel while being guided in the interior of the light guide plate 10 in a specified light guide direction (direction from the side of the side surface 10a toward the side surface 10b).

With the liquid crystal display apparatus 1 of the present embodiment, furthermore, white light from the white light-emitting diodes 26 and infrared light from the infrared light-emitting diodes 27 of the linear light-emitting diode unit 9 that faces the side surface 10b enter this side surface 10b, and such white light and infrared light are progressively emitted toward the liquid crystal panel while being guided in the interior of the light guide plate 10 in a specified light guide direction (direction from the side of the side surface 10b toward the side surface 10a).

As a result of the above configuration, operations and effects similar to those of the aforementioned first embodiment can be manifested in the present embodiment. Moreover, with the liquid crystal display apparatus 1 of the present embodiment, the white light-emitting diodes 26 and infrared light-emitting diodes 27 (first and second light-emitting diode portions) are disposed so as to face each of the two mutually opposing side surfaces 10a and 10b of the light guide plate 10. Consequently, with the liquid crystal display apparatus 1 of the present embodiment, it is possible to easily obtain the favorable uniformity for white light required for image display and for infrared light required for detection of the object of detection in the aforementioned illumination light. In addition, because white light and infrared light are caused to enter from the two side surfaces 10a and 10b of the light guide plate 10 as described above in the liquid crystal display apparatus 1 of the present embodiment, even when the respective numbers of installed white light-emitting diodes 26 and infrared light-emitting diodes 27 are increased, favorable evenness in the illumination light can be obtained easily. Furthermore, because the intensity of infrared light can be increased with the liquid crystal display apparatus 1 of the present embodiment, even under environment where outside light such as sunlight is intense, it is possible to improve the detection precision of the optical sensors 25 easily and to enhance the touch panel functions in the touch panel easily as well, compared to the display apparatus in the first embodiment. Moreover, the liquid crystal display apparatus 1 of the present embodiment is advantageous in cases where making apparatuses thinner is particularly required rather than making frames narrower.

### Fourth Embodiment

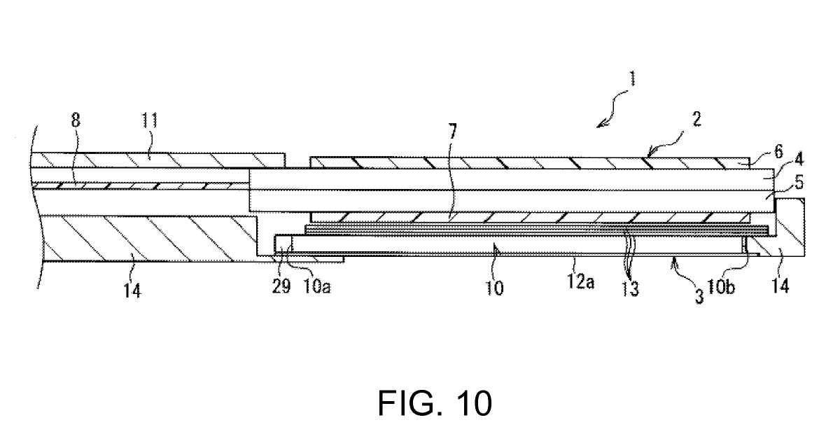

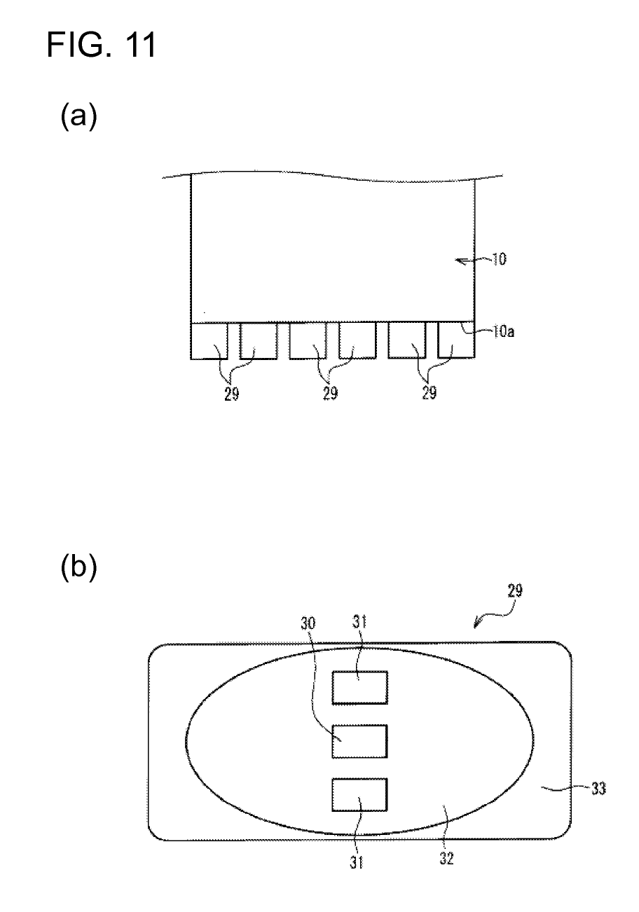

FIG. 10 is a schematic sectional view illustrating a liquid crystal display apparatus according to a fourth embodiment of the present invention. FIG. 11(a) is a plan view showing an example of arrangement of the light-emitting diode units shown in FIG. 10, and FIG. 11(b) is a diagram illustrating an example of a specific configuration of the aforementioned light-emitting diodes. In the figures, the main difference between the present embodiment and the aforementioned first embodiment is that instead of the linear light-emitting diode unit, individualized-type light-emitting diode units, each of which has a blue light-emitting element and infrared light-emitting elements mounted on a substrate and sealed by a fluorescent resin, are used. Note that the elements that are in common with the aforementioned first embodiment are labeled with the same reference characters, and a redundant description thereof will be omitted.

Specifically, as shown in FIGS. 10 and 11, in a liquid crystal display apparatus 1 of the present embodiment, a plurality of (e.g., six) light-emitting diode units 29 are disposed facing the side surface 10a of the light guide plate 10. In each of the light-emitting diode units 29, one blue light-emitting element 30 and two infrared light-emitting elements 31 are installed on a substrate 33, and these infrared light-emitting elements 31 and blue light-emitting element 30 are sealed by a fluorescent resin 32 on the substrate 33.

Furthermore, the blue light-emitting element 30, as in the case of the first embodiment, is included in a white light-emitting diode (first light-emitting diode portion) and emits blue light. Moreover, the fluorescent resin 32, as in the case of the first embodiment, is included in the white light-emitting diode (first light-emitting diode portion) and designed to emit white light by converting a portion of the blue light from the blue light-emitting element 30 into yellow light and mixing the blue light and the yellow light. In addition, the infrared light-emitting elements 31, as in the case of the first embodiment, are included in an infrared light-emitting diode (second light-emitting diode portion) and emit infrared light of a wavelength (e.g., 850 nm) in a specified range (e.g., 800 nm to 950 nm).

As a result of the above configuration, the present embodiment can exhibit operations and effects similar to those of the aforementioned first embodiment. Furthermore, the liquid crystal display apparatus 1 of the present embodiment uses light-emitting diode units 29 each having a so-called two-in-one structure in which one blue light-emitting element 30 and two infrared light-emitting elements 31 are packaged and mounted on the substrate 33, and these infrared light-emitting elements 31 and blue light-emitting element 30 are sealed by the fluorescent resin 32. Consequently, with the liquid crystal display apparatus 1 of the present embodiment, the manufacturing yield of the backlight device (backlight portion) 3 can be improved with ease, so the cost of the liquid crystal display apparatus 1 can easily be reduced. Specifically, because six light-emitting diode units 29 are used in the present embodiment, when a blue light-emitting element 30 or infrared light-emitting element 31 of any of the light-emitting diode units 29 can no longer emit light, it is sufficient if only this light-emitting diode unit 29 that has become a defective product is replaced. In contrast, with the linear light-emitting diode unit 9 of the first embodiment, if any of the blue light-emitting elements 26a or infrared light-emitting elements 27a can no longer emit light, this defective linear light-emitting diode unit 9 may have to be replaced in its entirety.

Note that besides the aforementioned description, it is also possible to use light-emitting diode units each having a so-called three-in-one structure in which (for example) one blue light-emitting element 30 and three infrared light-emitting elements 31 are mounted on a substrate 33, and these infrared light-emitting elements 31 and blue light-emitting element 30 are sealed by a fluorescent resin 32.

Note that all of the aforementioned embodiments merely show examples and are not restrictive. The technological scope of the present invention is prescribed by the claims, and all modifications within the scope equivalent to the configurations described therein are also included in the technological scope of the present invention.

For example, in the aforementioned description, a case in which the present invention is applied to a liquid crystal display apparatus equipped with an edge-light-type backlight device was described as an example. However, the display apparatus of the present invention is not limited to this. It may be sufficient if the display apparatus includes a touch panel, a display portion having a plurality of pixels, and a backlight portion that irradiates the aforementioned display portion with illumination light, with this display apparatus being such that the touch panel includes optical sensors that are provided in pixel units and that detect infrared light, and the backlight portion includes a first light-emitting diode portion which can emit white light, a second light-emitting diode portion which emits infrared light, and a substrate on which the first and second light-emitting diode portions are integrally provided. Specifically, the present invention can be applied to semi-transmissive-type liquid crystal display apparatus as well as various other types of non-self-light-emitting-type display apparatus.

Moreover, besides the aforementioned description, the present invention can also be applied to a display apparatus equipped with a direct-type backlight device (backlight portion) in which the aforementioned linear light-emitting diode unit or light-emitting diode units are provided so as to face the liquid crystal panel.

However, in terms of ability to easily achieve a lower profile of the display apparatus, the case of using an edge-light-type (side-light-type) backlight device in which first and second light-emitting diode portions are disposed so as to face at least one side surface of the light guide plate as in the case of the aforementioned embodiments is more preferable.

In addition, the aforementioned description involves a case in which a blue light-emitting element that emits blue light and a fluorescent resin that is provided on the substrate so as to seal the blue light-emitting element and that emits white light by converting a portion of the blue light into yellow light and mixing the blue light and the yellow light are used in a white light-emitting diode (first light-emitting diode portion). However, as long as the first light-emitting diode portion of the present invention can emit white light, there is no restriction on the first light-emitting diode portion. Specifically, it is possible to use, for example, a light-emitting diode which has a light-emitting element that emits light of a first color other than blue light, such as ultraviolet light, and a fluorescent resin that converts a portion of the light of the first color from this light-emitting element into light of a second color having a complementary color relationship with this first-color light and which emits white light by mixing the first-color light and the second-color light. Furthermore, it is also possible to use a so-called three-in-one light-emitting diode in which RGB light-emitting diodes that individually emit the respective colors, red (R), green (G), and blue (B) are integrally provided.

Nevertheless, the case of using blue light-emitting elements that emit blue light as in the aforementioned respective embodiments is preferable from the standpoint that the backlight portion can be configured at a lower cost. Moreover, blue light-emitting elements are superior to other light-emitting elements in terms of high luminance, long lifespan, and reliability, and are therefore preferable also from the standpoint that a high-performance backlight portion can be configured with ease.

In addition, in the aforementioned description, the case of using optical sensors that are integrally provided on the active matrix substrate of a liquid crystal panel (display portion) was described. However, optical sensors of the present invention are not limited to these, and optical sensors provided separately on the active matrix substrate can also be used.

However, the case of using optical sensors integrally provided on the active matrix substrate as in the aforementioned respective embodiments is preferable from the standpoint that a compact display apparatus equipped with a touch panel can be configured easily.

Furthermore, besides the aforementioned description, it is also possible to employ a configuration in which optical sensors (light-receiving elements) that receive white light (visible light) are provided in pixel units and also in an integrated manner on an active matrix substrate, for example, and the touch panel drive portion uses the detection results of the two optical sensors that respectively detect infrared light and white light to perform specified touch panel functions such as a user-operated input instruction detection action. Moreover, a configuration is also possible in which a luminance sensor that detect the brightness of outside light such as sunlight is provided, and the touch panel drive portion uses the detection results of the luminance sensor to perform the aforementioned specified touch panel functions.

### INDUSTRIAL APPLICABILITY

The present invention is useful for a display apparatus with a simple structure that can prevent a drop in display performance while ensuring sufficient detection precision regardless of the surrounding environment even when the detection precision in the touch panel is increased.

### DESCRIPTION OF REFERENCE CHARACTERS

1 liquid crystal display apparatus
2 liquid crystal panel (display portion)
3 backlight device (backlight portion)
5 active matrix substrate
9, 9′ linear light-emitting diode unit
10 light guide plate
10a, 10b side surface
16 touch panel drive portion (touch panel)
20 sensor column driver (touch panel)
21 sensor row driver (touch panel)
22 buffer amplifier (touch panel)
25 optical sensor (touch panel)
26 white light-emitting diode (first light-emitting diode portion)
26a blue light-emitting element (first light-emitting diode portion)
26b fluorescent resin (first light-emitting diode portion)
27, 27′ infrared light-emitting diode (second light-emitting diode portion)
27a infrared light-emitting element (second light-emitting diode portion)
27b transparent resin (second light-emitting diode portion)
28 substrate
29 light-emitting diode unit
30 blue light-emitting element (first light-emitting diode portion)
31 infrared light-emitting element (second light-emitting diode portion)
32 fluorescent resin (first light-emitting diode portion)
33 substrate

1. A display apparatus comprising a touch panel, a display portion having a plurality of pixels, and a backlight portion that irradiates said display portion with illumination light,
wherein said touch panel includes optical sensors that are provided in a unit of said pixels and that detect infrared light, and
wherein said backlight portion includes a first light-emitting diode portion that can emit white light, a second light-emitting diode portion that emits infrared light, and a substrate on which said first and second light-emitting diode portions are integrally mounted.

2. The display apparatus according to claim 1, wherein said first and second light-emitting diode portions are provided alternately and linearly on said substrate in said backlight portion.

3. The display apparatus according to claim 1, wherein said first light-emitting diode portion includes a blue light-emitting element that is installed on said substrate and that emits blue light and a fluorescent resin that is provided on said substrate so as to seal said blue light-emitting element and that emits said white light by converting a portion of said blue light into yellow light and mixing said blue light and said yellow light, and
said second light-emitting diode portion includes an infrared light-emitting element that is installed on said substrate and that emits said infrared light and a transparent resin that is provided on said substrate so as to seal said infrared light-emitting element.

4. The display apparatus according to claim 3, wherein in said second light-emitting diode portion, a plurality of said infrared light-emitting elements are sealed by said transparent resin on said substrate.

5. The display apparatus according to claim 1, wherein a blue light-emitting element that is included in said first light-emitting diode portion and that emits blue light and an infrared light-emitting element that is included in said second light-emitting diode portion and that emits infrared light are installed on said substrate in said backlight portion, and
wherein said backlight portion is provided with a fluorescent resin provided on said substrate so as to seal said blue light-emitting element and said infrared light-emitting element, the fluorescent resin emitting said white light by converting a portion of said blue light into yellow light and mixing said blue light and said yellow light.

6. The display apparatus according to claim 1, wherein said backlight portion comprises a light guide plate, and
wherein said first and second light-emitting diode portions are disposed so as to face at least one side surface of said light guide plate in said backlight portion.

7. The display apparatus according to claim 6, wherein said first and second light-emitting diode portions are disposed so as to face each of two mutually opposing side surfaces of said light guide plate in said backlight portion.

8. The display apparatus according to claim 1, wherein a liquid crystal panel is used for said display portion, and
wherein said optical sensors are provided integrally on an active matrix substrate of said liquid crystal panel.
